(19) United States
(12) Patent Application Publication
(10) Pub. No.: US 2008/0112231 A1
(43) Pub. Date: May 15, 2008

(54) Semiconductor devices and methods of manufacture thereof

(76) Inventor: Danny Pak-Chum Shum, Poughkeepsie, NY (US)

Correspondence Address: SLATER & MATSIL LLP, 17950 PRESTON ROAD, SUITE 1000, DALLAS, TX, 75252, US

(21) Appl. No.: 11/595,439

(22) Filed: Nov. 9, 2006

(51) Int. Cl. G11C 16/04

(52) U.S. Cl. 365/185.27

(57) ABSTRACT

A method of operating a memory array includes providing an array of memory cells arranged in rows and columns. Each column comprises a NAND unit cell including a plurality of memory cells coupled together serially. The plurality of memory cells of each NAND unit cell share a common well. The common well of each column is separated from common wells of adjacent columns by an isolation region. Each NAND unit cell includes a select gate transistor coupled to a memory cell in the column. A source of the select gate transistor is coupled to the common well of the NAND unit cell. The method includes accessing a first memory cell in a column by biasing the common well of the NAND unit cell of the first memory cell differently than the common well of other NAND unit cells are biased.

### TECHNICAL FIELD

The present invention relates generally to the manufacture of semiconductor devices, and more particularly to structures and methods of manufacturing flash memory devices, and methods of operating flash memory devices.

### BACKGROUND

Semiconductor devices are used in many electronic and other applications. Semiconductor devices comprise integrated circuits that are formed on semiconductor wafers by depositing many types of thin films of material over the semiconductor wafers, and patterning the thin films of material to form the integrated circuits.

One type of semiconductor device is a memory device, in which data is typically stored as a logical “1” or “0.” Memory devices may be static or dynamic. Dynamic memory devices need to be refreshed to “remember” the data, whereas static memory devices do not need to be refreshed to retain stored data.

One type of static memory device, also referred to in the art as a non-volatile memory (NVM) device, is a flash memory device. A flash memory device is an electrically erasable programmable read only memory (EEPROM) that is commonly used in computers, gaming systems such as MP3 players, iPOD™ by Apple Computer, Inc., or in the mass storage market (i.e., memory sticks, digital cameras, or mobile phones), as examples, although flash memory devices may alternatively be used in other applications, such as in security chip applications, set top boxes, electronically encoded smart cards, or automotive applications such as microcontrollers for dashboards, emission control, airbag, brakes, and temperature controllers, as examples, or other embedded flash applications, as well. Flash memory devices do not require power to retain stored data: they retain data even when the power source is disconnected. In flash memory devices, in-circuit wiring may be used to erase predetermined sections or blocks of the chip by applying an electrical field to the entire chip, for example.

Flash memory devices typically comprise an array of flash memory cells. Flash memory cells are accessible for programming and retrieving data by an array of wordlines and bitlines coupled to the array of flash memory cells. Each flash memory cell comprises a floating gate and a control gate, which are separated by a thin insulator. Flash memory cells store a charge in the floating gate and are programmed using Fowler-Nordheim tunneling by applying a relatively high voltage to the control gate as in a NAND architecture for example, or channel hot electron injection from the channel and the drain regions by adding electrical voltages to the control gate and the drain regions to reduce the gate dependency, for example.

Recent flash memory applications include “embedded flash memory” and system on a chip (SoC) devices, in which an array of flash memory cells and peripheral circuitry for the flash memory cells are formed together with microcontrollers or processors on a single chip or integrated circuit. The peripheral circuitry may comprise high voltage circuits, e.g., for column/row decoders or drivers, charge pumps, transfer gates, or other logic circuits for the microcontrollers or processors, and other types of devices that may comprise transistors, diodes, bandgap devices, capacitors, inductors, and linear devices, as examples, although other types of devices may be included in the peripheral circuitry. Alternatively, flash memory devices may comprise separate chips that are accessed and programmed by devices on other chips comprising the peripheral circuitry, for example.

Flash memory is a relatively new technology, and improvements are needed in the architecture of memory arrays and programming schemes. Furthermore, there are limitations in further reducing the size of flash memory cells in the industry.

Thus, what are needed in the art are improved flash memory designs and architectures.

### SUMMARY OF THE INVENTION

These and other problems are generally solved or circumvented, and technical advantages are generally achieved, by preferred embodiments of the present invention, which provide novel structures and methods of manufacturing and operating flash memory cell arrays.

In accordance with a preferred embodiment, a method of operating a memory array includes providing an array of memory cells arranged in rows and columns. Each column comprises a NAND unit cell including a plurality of memory cells coupled together serially. The plurality of memory cells of each NAND unit cell share a common well. The common well of each column is separated from common wells of adjacent columns by an isolation region. Each NAND unit cell includes a select gate transistor coupled to a memory cell in the column. A source of the select gate transistor is coupled to the common well of the NAND unit cell. The method of operating the memory array includes accessing a first memory cell in a column by biasing the common well of the NAND unit cell of the first memory cell differently than the common well of other NAND unit cells are biased.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 and 2 are schematics illustrating less-preferred embodiments of the present invention;

FIG. 3 is a schematic of a column of flash memory cells with isolated p wells arranged in a NAND configuration in accordance with a preferred embodiment of the present invention;

FIG. 4 shows a cross-sectional view of a device arranged in accordance with the schematic of FIG. 3;

FIG. 5 shows two columns of flash memory cells separated by a shallow trench isolation (STI) region in accordance with an embodiment of the present invention;

FIG. 6 shows a top view of a flash memory device in accordance with an embodiment of the present invention;

FIG. 7 is a schematic of the device shown in FIG. 6;

FIG. 8 is a top view of a device illustrating metallization connections of a flash memory device in accordance with an embodiment of the present invention;

FIG. 9 shows a cross-sectional view of a portion of a flash memory device in accordance with an embodiment of the present invention;

FIG. 10 is a schematic of a column of flash memory cells in accordance with another embodiment of the present invention;

FIG. 11 shows a cross-sectional view of a portion of the flash memory device of FIG. 10; and

FIG. 12 shows two columns of flash memory cells separated by a deep trench isolation (DTI) region in accordance with an embodiment of the present invention.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely, implemented in flash memory cell arrays. The invention may be implemented in embedded flash memory devices where peripheral circuitry such as row and column decoders, sense amplifiers, high voltage devices, logic devices, and other circuitry, as examples, are also formed on the same device. The invention may also be applied, however, to stand-alone flash memory arrays that do not have built-in or on-chip support circuitry and devices, for example, in the high density mass storage market. Embodiments of the present invention may also be implemented in other types of memory arrays and devices, for example.

Flash memory devices are typically formed using a triple well configuration in a bulk substrate: a substrate has a first dopant type, e.g., P type, and is considered a first well, a second well is formed in the substrate of a second dopant type, e.g., an N-well, and a third well is formed within the second well comprising the first dopant type, e.g., a P well. Alternatively, the first well and third well may comprise N-type and the second well may comprise P-type, for example. The third well of a flash memory device is often referred to in the art as a “body,” for example. The use of a triple well in flash memory enables electrical bias on the body. However, if a flash memory array is formed on an SOI substrate, a triple well may not be required, for example. When formed on an SOI substrate, the second well of the flash memory array may be replaced by the buried oxide (BOX) layer that ensures the proper bias of the body, for example.

Flash memory cells typically comprise transistors with double gates: a floating gate that is used to store information, and a control gate that controls the programming of the floating gate.

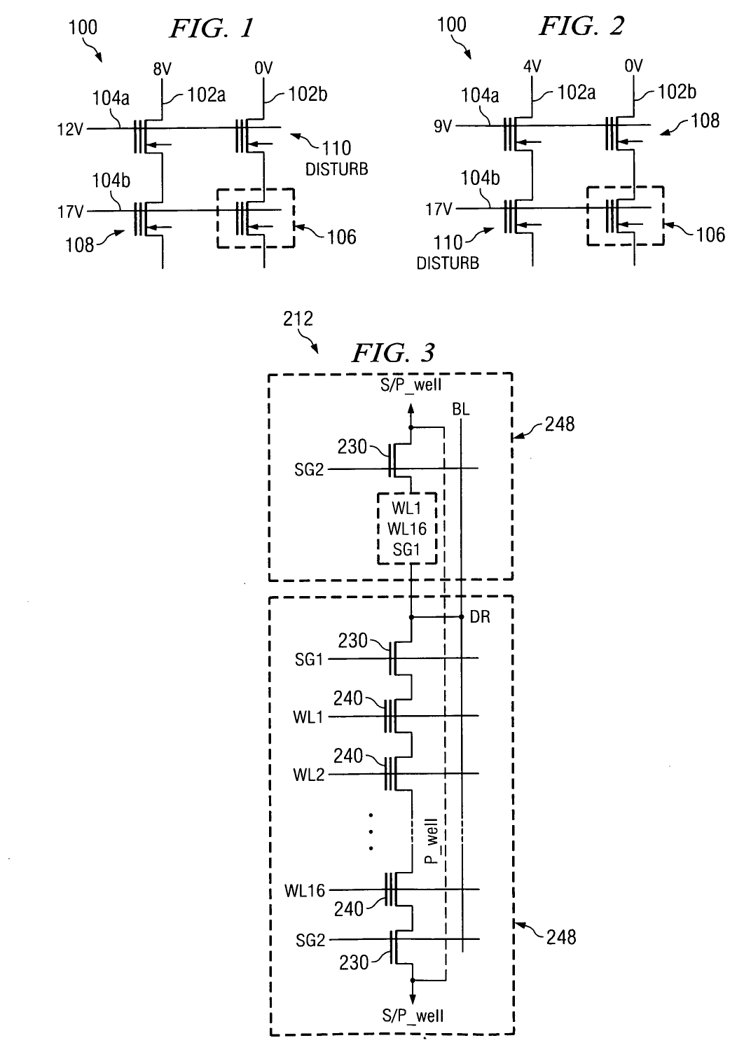

FIGS. 1 and 2 are schematics 100 illustrating less-preferred embodiments of the present invention. For example, in FIG. 1, four flash memory cells are shown arranged in a NAND architecture, wherein the flash memory cells (e.g., the four floating gate transistors) have a common P well or body.

Flash memory cells require a relatively high amount of voltage to program them, such as about 17 volts or higher. A NAND architecture for a flash memory array may be used to achieve a dense memory array, e.g., in a NAND architecture shown in FIGS. 1 and 2 wherein all of the flash memory cells in the memory array share a common P well. A NAND architecture saves space on an integrated circuit by the serial connection of the flash memory cells, which avoids requiring a contact for each source and drain of the flash memory cells, which is required in a NOR architecture, for example.

In a NAND architecture, a column of the serially connected flash memory cells is selected using a select gate transistor (not shown) at either end of the string of flash memory cells. However, in FIGS. 1 and 2, when one of the flash memory cells is programmed, adjacent memory cells may be disturbed by being subjected to high voltage levels. In general, it is desirable not to expose unselected flash memory cells during a programming operating to a gate to channel voltage difference of about 10 V or greater in a flash memory array, for example.

As an example, in FIGS. 1 and 2, the lower right floating gate transistor 106 may be programmed by applying 17 volts (V) on the gate, e.g., using a wordline 104b, and applying 0 V to the drain, e.g., using a bitline 102b. These voltages are applied to all transistors in each row and column, using the wordline 104b and bitline 102b, for example. The sources of all of the transistors in the memory array are serially connected and are electrically floated during programming as the gate of the source select gate transistor is connected to ground and the source is shorted to the common P well; e.g., Vs=V_well and Vsg2=0 V. The electrically floated sources of each transistor in the selected NAND unit cell will eventually reach the drain potential of the selected column, because all gates in the selected NAND unit cell during programming are subjected to a high voltage bias that causes the transistor to be electrically “on.” This configuration causes the electrical field to be uniform across the drain, channel, and source regions of all transistors in the selected NAND unit cell; thus, for example, this NAND architecture may be referred to as a uniform channel programming (UCP) flash memory array.

For example, in FIGS. 1 and 2, the sources of the upper left transistor and transistor 108 are floated to a bitline 102a bias of 8 V. Likewise, the sources of the transistors 110 and 106 are floated to a bitline 102b bias of 0 V. The flash memory cell 106 being programmed is subjected to a voltage difference of (17−0)V=17 V (gate to channel), programming the intended device 106.

However, to avoid programming the other devices or flash memory cells (e.g., the upper left transistor and transistors 108 and 110) in the memory array, other voltage levels may be applied to the wordline 104a and bitline 102a to bias the gates and drains of unselected flash memory cells, e.g., in order to avoid programming unintended devices (the upper left transistor and transistors 108 and 110).

In FIG. 1, for example, 12 V is applied to wordline 104a, and 8 V is applied to bitline 102a. The upper left transistor or flash memory cell has an applied gate to channel voltage difference of (12−8)V=4 V and is properly inhibited. Likewise, transistor 108 has an applied gate to channel voltage difference of (17−8)V=9 volts, and is also properly inhibited. However, the upper right transistor 110 has an applied gate to channel voltage difference of (12 to 0 V)=12 V, which is too high, resulting in a disturbed device 110.

Similarly, in FIG. 2, device 106 is programmed and another biasing scheme is used for the unselected or unintended devices, e.g., the upper left transistor and transistors 108 and 110. For example, if 9 V is applied to wordline 104a and 4 V is applied to bitline 102a, then the upper left transistor is properly inhibited, having a gate to channel voltage difference of (9 to 4 V)=5 V, and the upper right transistor 108 is properly inhibited, having a gate to channel voltage difference of (9 to 0 V)=9 V. However, transistor 110 has an applied gate to channel voltage difference of (17 to 4 V)=13 V, which is too high, resulting in a disturbed device 110.

Disturbed devices 110 can lead to device reliability problems over many reuses, resulting in failures in endurance cycling or failures over time, e.g., retention failures. Eventually, subjecting the flash memory cells to high voltage levels can destroy a flash memory cell, resulting in a bad pixel or bad vital data in a memory array, e.g., if the flash memory cells are used as memory in e-passport, bankcards, electronically encoded smart cards, or other applications that may lead to a loss of vital information.

Thus, flash memory cell architectures and methods of programming and manufacture thereof are needed that avoid disturbing devices: in particular, that avoid applying high voltage differences on flash memory cells that are adjacent to the flash memory cells being programmed.

In the less-preferred embodiments shown in FIGS. 1 and 2, each flash memory comprises a floating gate transistor having four terminals; a gate, a drain, a source, and a body or P well. Only three of the terminals, the gate, drain, and source, of each floating gate transistor are used for programming, e.g., for reading, erasing, and programming the floating gate transistor, and for biasing the flash memory cells not being programmed. The body of each transistor is common with all other transistors in the memory array; e.g., the structure comprises an array of flash memory cells formed on a silicon substrate that share a common P well.

Because all of the transistors or flash memory cells in each column are connected serially, the source and drain of each transistor is shared with adjacent transistors in a NAND architecture; for example, the drain of one transistor or cell becomes the source of the next cell, and so forth. The electrical potential of all source and drain terminals are controlled by two selected gate transistors at the ends of each column of flash memory cells. For example, in FIG. 2, the drain potential is connected by a gate and drain of a select gate transistor (not shown) coupled to the drain of transistor 108 in the right-most column, and the source potential is connected by a gate and source of a select gate transistor (also not shown) coupled to the source of transistor 106.

In preferred embodiments of the present invention, the body of floating gate transistors (the flash memory cells) in a column of a memory array are preferably common with other sources and bodies of floating gate transistors in the same column of a memory array, yet the sources or bodies in that column are isolated from the bodies of adjacent columns, so that another terminal, namely, the body, of the floating gate transistors in each column may also be used for biasing the floating gate transistors or flash memory cells. Using an additional terminal for biasing the flash memory cells provides greater flexibility in the programming of the flash memory cells in the memory array during a program operation, which allows an increased ability of avoiding disturbing adjacent devices in other columns by properly inhibiting the net vertical electrical field across the tunnel oxide, advantageously. The novel use of the body as an additional terminal for biasing the flash memory cells of a memory array also reduces the high voltage requirements that are needed to program the flash memory cells, as another advantage.

For example, in some preferred embodiments of the present invention, four terminals: the gate, drain, source, and also the P well (e.g., the body) of flash memory cells are used for biasing selected and unselected flash memory cells during a programming operation, to avoid subjecting the unselected flash memory cells to large voltage differences which may disturb the memory cells. Furthermore, advantageously, a high voltage bias applied to the gate can be split among the gate and the body of the flash memory cells, so that lower voltage potentials are required for accessing and programming the cells.

In accordance with a preferred embodiment of the present invention, for example, a method of operating a flash memory NAND array includes providing an array of flash memory cells arranged in rows and columns. Each column comprises blocks of NAND unit cells connected serially, in which a NAND unit cell includes a plurality of flash memory cells coupled together serially. The flash memory cells of each NAND unit cell along the same column share a common well. The common well of each column is separated from common wells of adjacent columns by an isolation region. Each NAND unit cell includes two select gate transistors which comprise FETs coupled in the column of flash memory cells. One select gate transistor, e.g., a first select gate transistor, functions as a drain select FET and is connected serially to the drain of a first flash memory cell in the column of flash memory cells. A second select gate transistor functions as a source select FET and is connected serially to the source of the last flash memory cell in the column of flash memory cells of the NAND unit cell. The source of the second source select gate transistor is coupled to the common well of the NAND unit cell. The method of operating the flash memory NAND array includes accessing a first flash memory cell in one of the columns by biasing the common well of the NAND unit cells of the selected column differently than the common well of the other NAND unit cells in other columns of the array are biased.

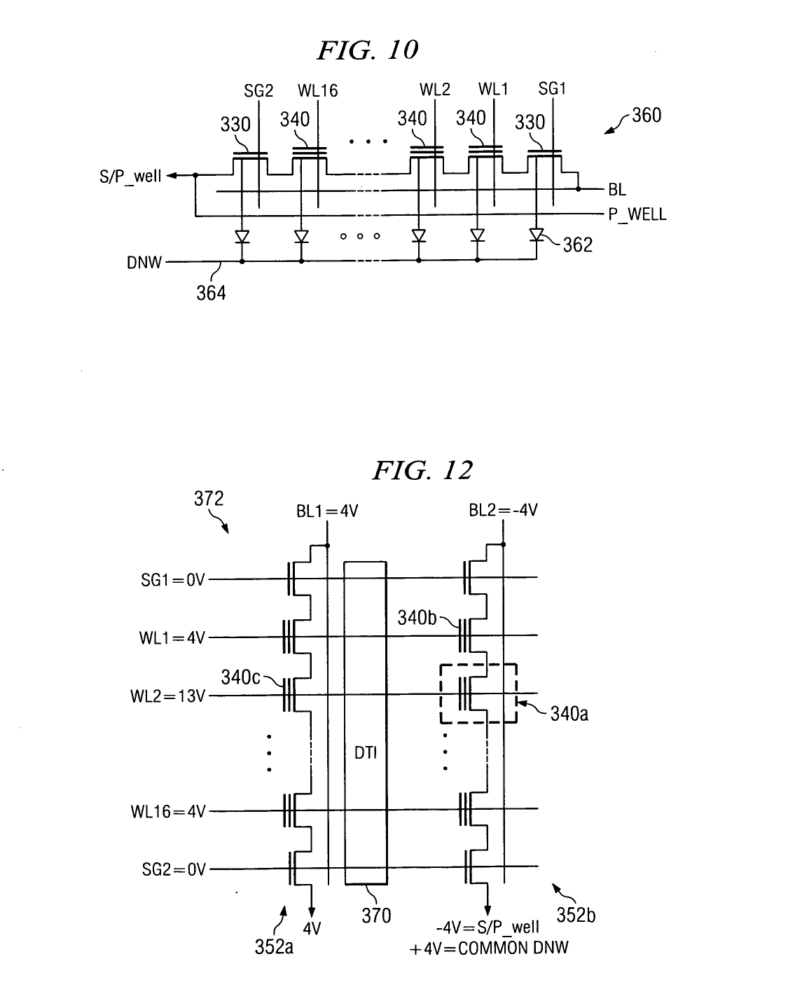

Embodiments of the present invention comprise structures and methods of operating and fabricating flash EEPROM isolated P well cells for a NAND architecture. Embodiments of the present invention may be implemented on SOI substrates, as shown in FIGS. 3 through 9, or they may be implemented in standard substrates with a deep trench isolation configuration, as shown in FIGS. 10 through 12, for example.

Referring next to FIG. 3, a schematic 212 is shown of a column of memory cells 240 with isolated P wells arranged in a NAND string or NAND unit cell configuration in accordance with a preferred embodiment of the present invention. The schematic 212 comprises a column of two NAND unit cells in an isolated P well architecture. One NAND unit cell 248 includes a serially connected string of sixteen floating gate cells 240 and two select gate transistors 230 having gates SG1 and SG2 coupled at either end of the string of floating gate cells 240. The floating gate cells 240 are also referred to herein as flash memory cells, floating gate transistors, or transistors, for example.

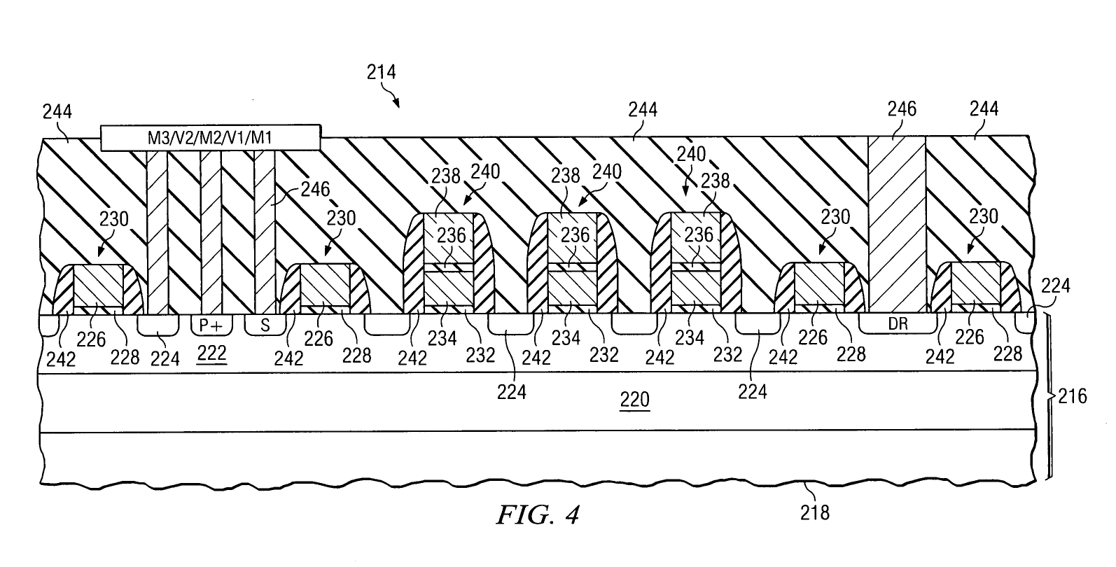

In a preferred embodiment, the schematic 212 with two NAND string or unit cells, includes sixteen flash memory cells 240 comprising floating gate transistors 240. Alternatively, the schematic 212 may include columns comprising different numbers of flash memory cells 240; for example, the NAND unit cell may comprise a variable number of floating gate transistors, depending on the application. The source and drain of adjacent flash memory cells 240 are coupled together and may comprise a single active area in a substrate 222, as shown in a cross-sectional view in FIG. 4 at 224, for example. A bitline BL is coupled to the drain contact DR of two select gate transistors 230 having gates SG1 along the column, indicated with gate SG1, WL1, WL16 in phantom (label DR in FIG. 3; also illustrated in FIG. 4 in a cross-sectional view as contact 246 on the right coupled to the drain DR). The two NAND unit cells 248 are preferably connected on a semiconductor device 214 serially in a 180° rotated layout in order to maximize layout efficiency, thus sharing one drain contact DR for the two drain select gate transistors 230, e.g., having gates SG1. This novel sharing concept of the drain DR contact 246 will be described further herein in more detail with reference to the semiconductor device 214 shown in a cross-sectional view in FIG. 4, for example.

Likewise, the two source select gate transistors 230 having gates SG2 are electrically shorted to the common P_well of the column and extend to the next gate SG2 of the next NAND unit cell (not shown in FIG. 3; see the cross-sectional view in FIG. 4 the contact 246 on the left coupled to the source S) for layout efficiency. The select gate transistor 230 having a gate SG1 together with the drain contact DR of the bitline BL ensures the selectivity of which NAND unit cell in this NAND column is to be programmed. The second select gate transistor 230 having a gate SG2 together with the source S shorted to the P well (P_well) prevents the flash memory cell 240 current from passing during programming to the next NAND unit cell 248, for example. The control gate of each of the flash memory cells 240 is coupled to a wordline decoder (not shown), as shown at WL1, WL2 . . . WL16. The P well of the flash memory cells 240 in the column is common for all of the flash memory cells 240 in the column.

Preferably, a memory array comprises a plurality of columns arranged as shown in the schematic 212 of FIG. 3, in accordance with an embodiment of the present invention, wherein the S/P_well, e.g., which is coupled to the source of the select gate transistor 230 with gate SG2 at the bottom and top of the NAND unit cells 248 in FIG. 3, of adjacent columns are electrically isolated from one another using isolation regions such as shallow trench isolation (STI) regions, to be described further herein.

FIG. 4 shows a cross-sectional view of a device 214 arranged in accordance with the schematic 212 of FIG. 3. In this embodiment, a workpiece 216 preferably comprises a silicon-on-insulator (SOI) substrate 216. The SOI substrate 216 preferably comprises a first layer of semiconductive material 218 that may comprise silicon, for example, attached to a buried oxide layer 220. The buried oxide layer 220 may comprise silicon dioxide or other insulating materials, and is also referred to herein as a buried insulating layer. A second layer of semiconductive material 222 is disposed on the other side of the buried oxide layer 220, as shown. The second layer of semiconductive material 222 is typically thinner than the first layer of semiconductive material 218, for example. The semiconductor material layers 218 and 222 may comprise Si, SiGe, Ge, or other semiconductor materials or combinations of semiconductive materials, as examples.

The first layer of semiconductive material 218 may comprise a substrate comprising a thickness of about 400 μm or greater, the buried oxide layer 220 may comprise a thickness of about 0.3 μm or less, e.g., about 200 to 400 nm, and the second layer of semiconductive material 222 may comprise a thickness of about 0.2 μm or less, as examples, although these layers may alternatively comprise other dimensions, for example. The second layer of semiconductive material 222 may be partially depleted or fully depleted, for example, according to its thickness. For example, a thicker layer 222 is generally considered a partially depleted SOI substrate, while a thinner layer 222 is considered a fully depleted SOI substrate. The first layer and second layer of semiconductive material 218 and 222 may be implanted with dopants, e.g., they may be N-type or P-type, for example. In the example shown, the first layer and second layer of semiconductive material 218 and 222 are P-type to form an N-channel flash memory. However, embodiments of the present invention may also comprise N-type layers 218 and 222 that form a P-channel flash memory device, for example.

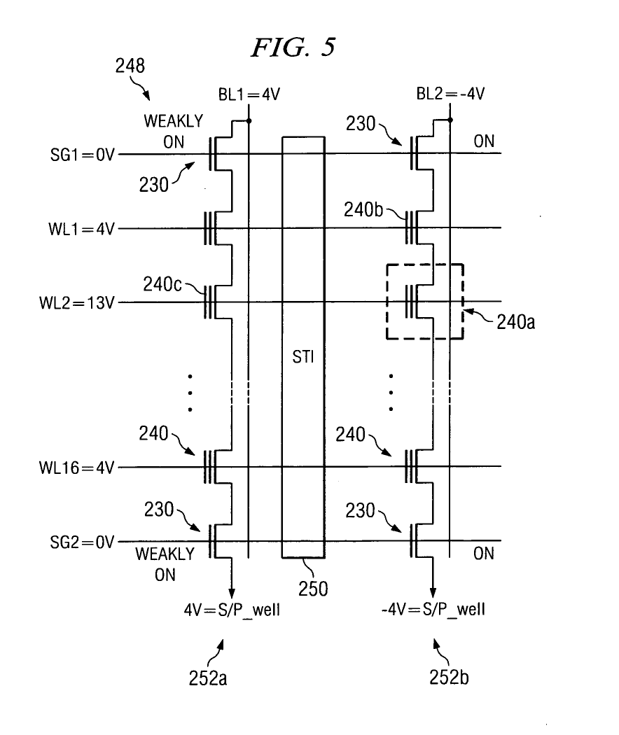

To manufacture the device 214, portions of the second layer of semiconductive material 222 are implanted with dopants to form source S and drain DR regions of transistors 230 (which comprise select gate transistors) and floating gate transistors 240 (which comprise flash memory cells) in the second layer of semiconductive material 218, as shown. STI regions are formed between columns of the flash memory cells or transistors 240 (not shown in FIG. 3; see STI region 250 in FIG. 5 in a top view and in FIG. 9 in a cross-sectional view). The STI regions 250 stop on top of buried oxide layer 220 to ensure isolation between adjacent columns of active regions, for example, columns 252a and 252b shown in FIG. 5.

Next, a plurality of different material layers are sequentially deposited over the second layer of semiconductive material 222, and the material layers are patterned and etched using lithography to form the transistors 230 and 240. Then an insulating material 244 that may comprise an inter-level dielectric (ILD), for example, is deposited over the transistors 230 and 240. Contacts 246 are formed in the insulating material 244 to make electrical contact with active areas (e.g., P+, S, and DR) of the second layer of semiconductive material 222, for example.

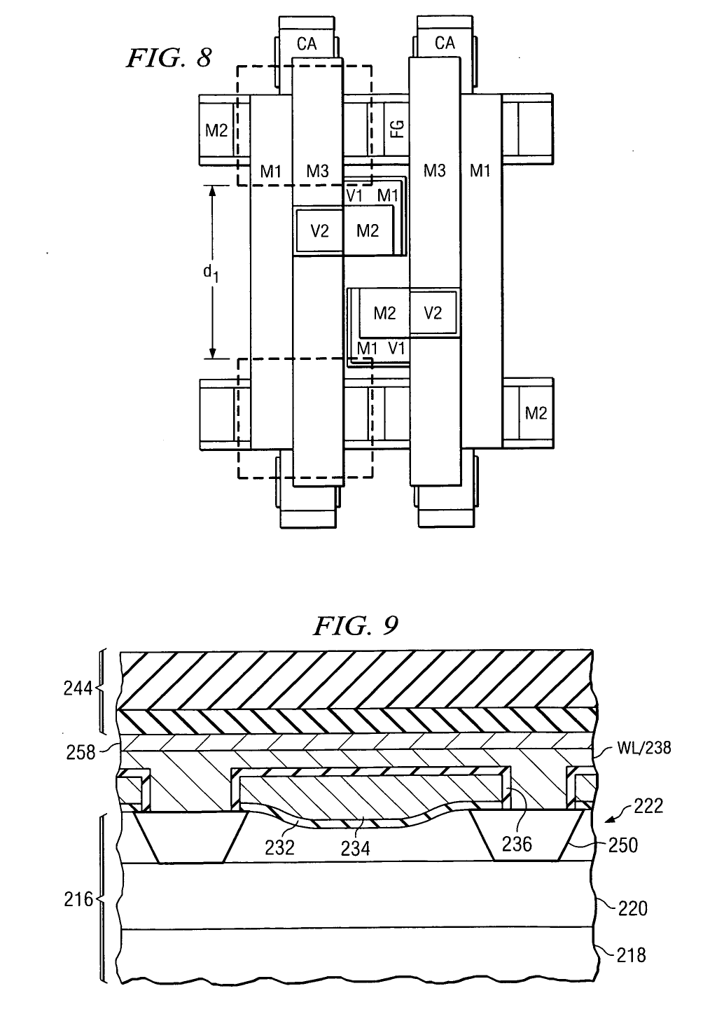

Referring to FIG. 4, the device 214 comprises an isolated P well NAND architecture. One select gate transistor 230 is disposed proximate the drain DR on the right side of the figure, and another select gate transistor 230 is coupled to the P well (e.g., active area P+ on the left) using a source S to P well (P+) contact to a metallization layer such as M3, for about 32 wordlines, for example. The contacts 246 may be formed in one or more metallization layers, such as metallization layers M1, M2, and/or M3 and via layers V1 and/or V2, as shown. Note that in FIG. 4, the metallization layers are shown collectively as a single layer; preferably, the metallization layers comprise sequentially deposited and patterned material layers (not shown), as shown in a top view in FIG. 8, to be described further herein.

Regarding the drain DR contact sharing mentioned with reference to FIG. 3, contact 246 makes contact to the drain DR side between two drain select gate transistors 230 having gates SG1. To access the left NAND unit cell, a proper bias scheme must be applied on contact 246, the gate SG1 of select gate transistor 230, WL1 thru WL16 of all flash memory cells 240, and finally the source of the select transistor gate 230 having gate SG2 which is electrically shorted to the P well with source/P_well contact 246. Likewise, a similar bias scheme must be applied to access to the right NAND unit cell of the DR contact 246, for example.

Referring to FIGS. 5 and 9, the STI regions 250 are formed through P wells of columns of flash memory cells 240, separating each column of flash memory cells 240 for isolated P well operation. The STI regions 250 also preserve the same well constructions to operate high voltage CMOS in peripheral regions of the semiconductor device (not shown) at a voltage level of greater than about 17 V simultaneously, for example.

FIG. 5 shows a schematic 248 of a NAND unit cell that includes two columns 252a and 252b of flash memory cells 240 in a memory array arranged in NAND unit cell configuration separated by an STI region 250 in accordance with a preferred embodiment of the present invention. The STI region 250 separates and electrically isolates the P well of column 252a from the P well of column 252b. The P well of column 252a may be coupled to a first voltage, and the P well of column 252b may be coupled to second voltage, wherein the second voltage is different than the first voltage. For example, in the embodiment shown, the P well of column 252a and the source of the select gate transistor SG2 of column 252a is coupled to 4 V, and the P well of column 252b and source of the select gate transistor SG2 of column 252b is coupled to a voltage of −4 V. This results in device 240b adjacent the programmed device 240a being properly inhibited, with a gate to channel voltage difference of less than or about 8 V. Likewise, device 240c is also properly inhibited, having a gate to channel voltage difference of less than about 9 V.

Advantageously, the isolated P wells of the columns 252a and 252b give a greater degree of freedom in biasing unselected flash memory cells 240. For example, by coupling the source of the select gate transistors 230 with gates SG2 in each column 252a and 252b to the P well of that column 252a and 252b, the source of the select gate transistors 230 having gates SG2 may be biased independently, e.g., sources of the select gate transistors 230 with gates SG2 are independently biasable. A column 252b containing a cell 240a selected for programming may be biased to one voltage, and a column 252a containing unselected cells may be biased to another voltage, for example.

In a preferred embodiment, a column 252b containing the cell 240a selected for programming is preferably biased to a voltage having an opposite polarity than the voltage used to bias columns 252a containing unselected cells such as cell 240c, for example. Also, advantageously, in accordance with embodiments of the present invention, unselected flash memory cells 240 are inhibited with a voltage difference between their gates, sources, and/or drains of less than about 10 V, for example.

In some embodiments, the common well of each column may be biasable to a predetermined voltage, and the common wells of adjacent NAND unit cells are biasable to different voltages. The predetermined voltage may comprise about ±10 volts or less, for example. At least one contact 246 may be coupled to each column of flash memory cells 240 and may be used to biasing the columns to the respective voltages, for example.

Table 1 below and FIG. 5 illustrate an example of a NAND isolated P well bias operation condition in accordance with a preferred embodiment of the present invention. The voltage levels described in Table 1 are exemplary; alternatively, other biasing schemes and voltage levels may be used.

TABLE 1

| | | | WL1- | | | | S1/ | S2/ |
|---|---|---|---|---|---|---|---|---|
| | SG1 | SG2 | 16 | WL_sel | BL1 | BL2_sel | PW1 | PW2 |
| Write | 0 | 0 | 4 | 13 | 4 | −4 | 4 | −4 |
| Erase | 4 | 4 | −13 | −13 | 4 | 4 | 4 | 4 |
| Read | 4.5 | 4.5 | 4.5 | 0 | 0 | 1 | 0 | 0 |

In this example, a flash memory cell 240a is selected for programming by selecting WL2 and BL2, e.g., by applying 13 V to WL2 and −4 V to BL2=a 17 V differential. In the operation of the flash memory array, write and read are a “bit” operation, for example, the wordline and bitline WL2 and BL2 are selected with the corresponding select gates SG1 and SG2 of select gate transistors 230 for a particular NAND unit cell e.g., in a column 252b. In an erase operation, a block operation is preferably used; for example, all select gate transistors 230 of the block selected for erase are selected to “on.”

Note that because the flash memory cells 240 are connected in series within one NAND unit cell in a column 252a or 252b, (e.g., between the select gate transistors 230 having gates SG1 and SG2), the number of contacts 246 (see FIG. 4) required for the NAND unit cells are minimized; e.g., a contact 246 for each flash memory cell 240 is advantageously not required, minimizing the size of the NAND unit cell. The sources and drains of the select gate transistors having gates SG1 and SG2 of the NAND unit cell are the only source and drain contacts 246 required to make contact with the flash memory cells of the NAND unit cell outside the NAND unit cell, e.g., to a connection external to the flash memory array. Therefore, the flash memory cells 240 may comprise much smaller devices and may comprise denser array structures that require less surface area of the integrated circuit.

As an example, in FIG. 5, again, the selected cell 240a may be programmed using 17 V, e.g., 13 V on WL2 and −4 V on BL2. The other wordlines WL1, and WL3 to WL16 have a voltage of 4 V applied, and the other bitlines BL1 (and other bitlines in the array, not shown) have 4 V applied. A voltage of 4 V is applied to BL1, and a voltage of −4 V is applied to BL2. The bodies (P_well) of cells 240 on BL1 have 4 V applied, and the bodies of cells on BL2 have −4 V applied. The sources of the select gate transistors 230 with gates SG2 of columns 252a and 252b are coupled to the common P_well of each column 252a and 252b, and have voltages of 4 V and −4 V, respectively, applied. The select gate transistors 230 with gates SG1 and SG2 along BL2 are selected to “turn on” electrically, for example, have 0 V applied to the gates; thus passing −4 V from the drain of the select gate transistor with gate SG1 to the channel, and enabling the flash memory cell 240a to be programmed. Likewise, the select gate transistors 230 with gates SG1 and SG2 of BL1 are selected to turn-on weakly, for example, under the same gate bias, thus passing 4 V from the drain of the select gate transistor 230 with gate SG1 to the channel and inhibiting the programmed disturb of cell 240c.

Thus, unselected cells 240 (such as cell 240c) on WL1 and WL3 to WL16 in column 252a have a voltage difference of 0 V applied to the gate and drain. The unselected cell 240c on WL2 has a voltage difference of less than 9 V applied, which is an acceptable amount of voltage difference that does not produce a gate disturb for the cell 240c, advantageously.

A method of operating a flash memory array 248 shown in FIG. 5 in accordance with an embodiment of the present invention may comprise accessing a flash memory cell 240a in a column 252b by biasing the common well S/P_well of the NAND unit cell (e.g., in column 252b) of the flash memory cell 240a differently than the common well P_well of other NAND unit cells e.g., in column 252a are biased. Accessing the flash memory cell 240a may comprise reading or writing to the flash memory cell 240a, for example. Biasing the common well S/P_well of the NAND unit cell of the flash memory cell 240a differently than the common well P_well of other NAND unit cells are biased may comprise biasing the common well S/P_well of the NAND unit cell of the selected flash memory cell 240a with an opposite polarity (e.g., −4 V) than the common well P_well of NAND unit cells of unselected flash memory cells (e.g., 240c and 240) of other columns 252a are biased (e.g., +4 V), in some embodiments, for example. As another example, the common well P_well of the selected flash memory cell 240a may be biased with a voltage of −4 V on the selected column 252b while the common well P_well of the unselected flash memory cells in unselected columns 252a may be biased with a different voltage having an opposite polarity or zero voltage, e.g., +3 V, +5 V, other positive voltage levels, or 0 V. Note that the bitline BL1 bias in unselected columns 252a will follow the new bias voltage levels of the common P_well of the unselected columns 252a. Alternatively, other voltage levels may be used for biasing the common wells P_well of the columns 252a and 252b, for example.

Each flash memory cell 240 in a row is preferably coupled to a wordline WL1, WL2, . . . WL16, for example, and biasing the common well S/P_well of the NAND unit cell of the selected flash memory cell 240a differently than the common well P_well of other NAND unit cells are biased may comprise biasing the common well S/P_well of the NAND unit cell of the flash memory cell 240a to a first voltage (e.g., −4 V). A method of operating the flash memory array 248 may comprise biasing a wordline WL2 of the flash memory cell 240a to a second voltage (e.g., +13 V), wherein the second voltage (+13 V) comprises a voltage having an opposite polarity (+) than the first voltage (−4 V), e.g., the first voltage has an opposite polarity (−) than the second voltage, in some embodiments, for example. Advantageously, biasing the common well S/P_well of the NAND unit cell of a selected flash memory cell 240a differently than the common well P_well of other NAND unit cells are biased prevents disturbing unselected flash memory cells such as cells 240b and 240c in columns and rows adjacent to the selected flash memory cell 240a.

According to a preferred embodiment of the present invention, for example, a method of operating a flash memory array 248 comprises providing an array of flash memory cells 240 arranged rows and columns 252a and 252b, each column 252a and 252b of flash memory cells 240 sharing a common well P_well, the common well P_well of each column 252a and 252b being isolated from adjacent columns 252b or 252a of the flash memory cells 240 by an isolation region (e.g., STI region 250). Each flash memory cell 240 comprises a gate, a drain, a source, and a body. The body of each flash memory cell 240 is coupled to the common well P_well of the column 252a or 252b, and each column 252a and 252b of flash memory cells 240 is coupled together serially in a string. The sources of flash memory cells 240 in each string are coupled to the drains of adjacent flash memory cells 240, and each column 252a or 252b comprises blocks of NAND unit cells including a first select gate transistor 230 comprising gate SG1 coupled to a drain of a flash memory cell 240 at one end of the string and a second select gate transistor 230 comprising gate SG2 coupled to a source of a flash memory cell 240 at an opposite end of the string. A drain contact (e.g. contact 246 shown in FIG. 4 coupled to drain DR) is shared between at least two first select gate transistors 230 having gates SG1 of at least two NAND unit cells. The method of operating the flash memory array 248 includes selecting a flash memory cell 240a in one of the columns 252b by applying a first voltage (0 V) to a gate SG1 of the first select gate transistor 230 of all columns 252a and 252b, applying a second voltage (0 V) to a gate SG2 of the second select gate transistor 230 of all columns 252a and 252b, applying a third voltage (4V applied to BL1) to a drain of the first select gate transistor 230 having gate SG1 in columns 252a of unselected flash memory cells 240 and 240c, applying a fourth voltage (−4 V applied to BL2) to a drain of the first select gate transistor 230 having gate SG1 in the column 252b of the selected flash memory cell 240a, applying a fifth voltage (4 V) to a source of the second select gate transistor 230 having gate SG2 in columns 252a of unselected flash memory cells 240, and applying a sixth voltage (−4 V) to the common well P_well and to a source S of the second select gate transistor 230 having gate SG2 in the column 252b of the selected flash memory cell 240a, while programming the selected flash memory cell 240a.

Again, these voltage levels are merely examples of voltages that may be used for the first, second, third, fourth, fifth and sixth voltages; alternatively, other voltage levels may also be used. Applying the first voltage, the second voltage, the third voltage, the fourth voltage, the fifth voltage, and the sixth voltage preferably comprises applying a voltage of about −10 V to about +10 V, in some embodiments, for example. Applying the first voltage, the second voltage, the third voltage, the fourth voltage, the fifth voltage, and the sixth voltage may comprise applying a total voltage difference across the gates to channels of the flash memory cells 240, 240b, and 240c (e.g., the unselected cells) in the array 248 of about 10 V or less, for example.

The method of operating the flash memory array 248 may include isolating columns 252a of NAND unit cells containing unselected flash memory cells 240 and 240c using the second select gate transistor 230 having gate SG2 in each column 252a, preventing a leakage current from flowing to other NAND unit cells along the same column or in the isolated columns of NAND unit cells containing unselected flash memory cells 240 and 240c when the selected flash memory cell 240a is selected. The source of each second select gate transistor 230 having gate SG2 may be shorted to an isolated contact (contact 246 shown connected to source S in FIG. 4) coupled to the common well P_well of the column 252a or 252b, and the isolated common wells P_well of the columns 252a and 252b may be independently biasable, for example. Programming the selected flash memory cell 240a may comprise applying a seventh voltage (13 V) to a wordline WL2 coupled to the gates of a row of flash memory cells (e.g., the row containing cells 240c and 240a), the selected flash memory cell 240a being disposed on the row that the seventh voltage is applied to. An eighth voltage (4 V) may be applied to wordlines WL1, WL3, . . . WL16) coupled to the gates of rows of unselected flash memory cells 240 and 240b, for example. Programming the selected flash memory cell 240a may comprise applying a gate to channel voltage differential of about 15 V or greater to the selected flash memory cell 240a, for example.

Advantageously, the isolation region (STI region 250) separating the common well P_well of the columns 252b from adjacent columns 252a, applying the fifth voltage to the source of the second select gate transistor 230 having gate SG2 in columns 252a of unselected flash memory cells, and/or applying the sixth voltage to the common well P_well and to the source S of the second select gate transistor 230 having gate SG2 in the column 252b of the selected flash memory cell 240a may reduce a program or a gate disturb along a wordline WL2 or bitline BL2 coupled to the selected flash memory cell 240a, for example.

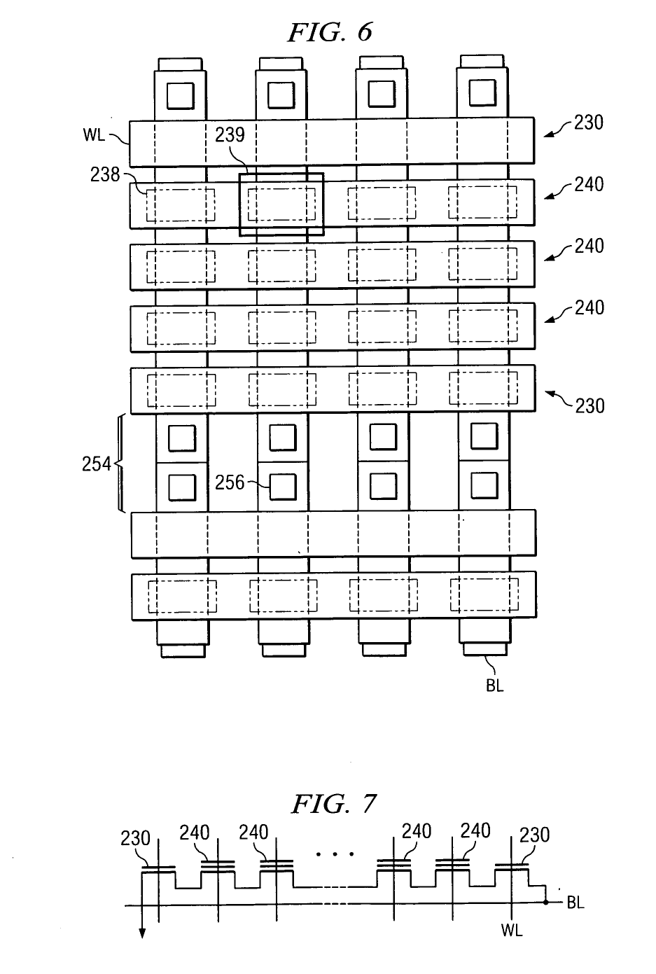

FIG. 6 shows a top view of a memory array in accordance with a preferred embodiment of the present invention, for the NAND architecture with a cross-section through a BL on an SOI substrate shown in FIG. 4. The wordlines WL are disposed over the flash memory cells 240 and the select gate transistors 230, as shown. The bitlines BL are disposed in an underlying conductive line layer. The source/P well strap region is shown at 254, and contacts and vias making electrical connections to the source/P well strap region 254 are shown at 256. The floating gates of the flash memory cells 240 are shown at 238 (e.g., that also comprise a portions of the wordlines WL), for example, and a representative unit cell of the memory cells 240 is shown at 239. FIG. 7 is a schematic of a portion of the device shown in FIG. 6.

In FIG. 6, a local data line is formed by the drain contact and diffusion through the serially connected transistors 230 and 240 (not shown in FIG. 6), which function as pass gates, for example. The global data lines may be formed in a metallization M1 layer, as shown. The source line comprises one S/P_well strap for 32 WLs, for example. The strap cell, e.g., in the source/P well strap region 254 is formed by source n+ diffusion shorted to the p+P well contact through M1/via/M2 levels, for example. The contact to the M3 layers is made through vias and the M2 level that is disposed on top of the STI region 250 (not shown in FIG. 6). Advantageously, this architecture adds only a few minimum feature size square area (F²) to the overall NAND architecture, which is negligible, for example.

FIG. 8 is a top view of a device illustrating metallization and conductive material connections of a memory device in accordance with a preferred embodiment of the present invention. A source strap cell is shown, wherein an S/P well contact is formed in a plurality of metallization layers. For example, layer M1 shows a bottom-most metallization layer, M2 shows a metallization layer above layer M1, and M3 shows a top-most metallization layer above layer M2. Via layer V1 is disposed between layer M1 and M2, and via layer V2 is disposed between layer M2 and M3. CA represents a contact layer, and FG represents a layer the floating gates of the flash memory cells 240 are formed in, for example. The S/P well contact is formed in layer M3, e.g., in the wordline metal layer, and is continued in layer M1, e.g., in the bitline layer, for example. The S/P_well contact to the M3 layer is made by 32 WLs, and is continued on the M1 bitline layer. The distance d₁ represents a distance between two underlying flash memory cells 240 of the memory device, for example. Advantageously, the distance d₁ may comprise about 0.5 μm or less, for example, in accordance with embodiments of the present invention, although alternatively, dimension d₁ may comprise other dimensions.

FIG. 9 shows a cross-sectional view of a portion of a memory device in accordance with a preferred embodiment of the present invention. The cross-sectional view in FIG. 9 is rotated 90 degrees from the cross-sectional view in FIG. 4. A wordline, e.g., comprising a control gate 238 is shown at WL on top of an oxide/nitride/oxide (ONO) layer or control gate oxide 236 disposed over a floating gate 234 which is disposed over a tunnel gate dielectric 232, to be described further herein. The wordline WL/238 may have a silicide 258 formed over the top surface thereof, as shown. An insulating layer 244 comprising an ILD may be disposed over the wordline WL/238 and/or silicide 258, as shown. STI regions 250 are formed in the second semiconductive material 222 of the SOI substrate 216 so that they stop on the buried oxide 220 of the SOI substrate 216. The STI regions 250 are disposed between columns of the memory array shown in the cross-sectional view in FIG. 4, for example.

An example of a more detailed manufacturing process flow will next be described with reference to the cross-sectional views shown in FIGS. 4 and 9. The exemplary process flow may be used to manufacture a novel isolated P well NAND flash memory array on an SOI substrate 216 in an embedded chip, wherein peripheral circuitry (not shown) is formed on the same chip. Note that in FIGS. 4 and 9, a region of the semiconductor device 214 is shown where flash memory cells 240 are formed; the semiconductor device 214 may also include a region where peripheral devices are formed. The peripheral devices may comprise support circuitry and devices for the flash memory cells, for example. The peripheral devices may comprise logic devices such as logic devices, e.g., for microcontrollers or processors, high voltage devices, low voltage devices, power devices, control devices for reading and writing to the flash memory cells, and/or combinations thereof, for example. The peripheral devices in the peripheral region may be operationally coupled to the flash memory cells in the flash memory region. In some embodiments, the peripheral devices may be adapted to perform functions unrelated to the accessing of information to or from the flash memory cells, for example.

First, the SOI substrate 216 is provided. The SOI substrate 216 includes a first layer of semiconductive material 218 that may comprise a workpiece or substrate. The first layer of semiconductive material 218 may include a semiconductor substrate comprising silicon or other semiconductor materials covered by an insulating layer, for example. The first layer of semiconductive material 218 may comprise silicon oxide over single-crystal silicon, for example. Compound semiconductors, GaAs, InP, Si/Ge, or SiC, as examples, may be used in place of silicon. A buried oxide layer 220 is disposed over the first layer of semiconductive material 218. A second layer of semiconductive material 22 is disposed over the buried oxide layer 220.

The second layer of semiconductive material 222 may comprise about 50 nm of Si formed over the buried oxide layer 220 having a thickness of about 200 nm, as examples, although layer 220 and 222 may comprise other materials and thicknesses, such as about 400 nm or less. The second layer of semiconductive material 222 may be implanted with dopants, e.g., comprising N-type or P-type dopants, for example. In the example shown, the SOI substrate 216 and the second layer of semiconductive material 222 are P-type to form N-channel flash memory. However, embodiments of the present invention may also comprise N-type layers 216 and 222 that form a P-channel flash memory device, for example.

Next, the STI regions 250 (see FIG. 9) are formed, e.g., by etching trenches in the second layer of semiconductive material 222. The etch process for the STI trenches may be adapted to stop on the buried oxide 220 of the SOI substrate 216, for example. The STI trenches may comprise a depth of about 0.2 μm or less, for example, although alternatively, the STI trenches may comprise other dimensions. In some embodiments, for example, the STI trenches comprise a depth within the substrate, e.g., within the second layer of semiconductive material 222 of about 400 nm or less. The STI trenches are filled with one or more insulating materials. For example, the STI trenches may be lined with an optional oxide liner and may then be filled with an insulating material that may comprise silicon dioxide, for example. Any excess insulating material may be removed from the top surface of the second layer of semiconductive material 222, e.g., using a chemical mechanical polishing (CMP) process.

Note that an optional sacrificial layer may be formed over the second layer of semiconductive material 222 prior to the formation of the STI regions 250. For example, a pad nitride and/or pad oxide (not shown) may be formed over the second layer of semiconductive material 222, and may be removed after the CMP of the STI regions 250.

Then CMOS wells are formed in the logic and periphery regions (not shown). For example, one or more layers of photoresist may be deposited and patterned, and P and N type dopants may be implanted to form the wells of CMOS devices, e.g., for logic and/or high voltage devices, not shown. The wells may also comprise the P well or body of the flash memory cells 240 in the flash memory region, for example.

Then the processing of the flash memory cell region of the semiconductor device 214 is continued. For example, a flash tunnel oxide 232 may be deposited over the second layer of semiconductive material 222. The flash tunnel oxide 232 is also referred to herein as a floating gate oxide 232, for example. The flash tunnel oxide 232 may comprise a thin insulating layer comprising an oxide, such as silicon dioxide or SiON, although the thin insulating layer may alternatively comprise high k dielectric materials, such as Al₂O₃ or HfSiON, combinations or multiple layers thereof, or combinations or multiple layers thereof with silicon dioxide, as examples, although other materials may also be used. The flash tunnel oxide 232 preferably comprises a thickness of about 20 nm or less, and in one embodiment, more preferably comprises a thickness of about 7 to 10 nm, as examples, although the flash tunnel oxide 232 may alternatively comprise other dimensions. The flash tunnel oxide 232 may be formed by thermal oxidation of the exposed second layer of semiconductive material 222 at an elevated temperature, typically at about 900 to 1,050 degrees C., for a few minutes in an oxygen or oxynitride environment, for example, although the flash tunnel oxide 232 may alternatively be formed by other methods. The thin insulating layer comprising the flash tunnel oxide 232 forms the floating gate oxide of the flash memory cell 240 in the second region 232. The thin insulating layer comprising the flash tunnel oxide 232 may not form over the top surface of the STI regions 250, because an oxide material such as the material used to fill the STI regions 250 generally does not oxidize, for example, as shown.

A floating gate material 234 comprising about 90 nm of lightly doped polysilicon, for example, is deposited over the flash tunnel oxide 232. The floating gate material 234 may comprise a layer of conductive material that preferably comprises a semiconductive material, and may alternatively comprise a metal or a semiconductor material and a metal, as examples. In one embodiment, the layer of conductive material 234 preferably comprises about 150 nm or less of polysilicon that is in-situ low doped, e.g., with N type dopants, for an N-channel flash memory device. Alternatively, the layer of conductive material 234 may comprise other materials and/or may be in-situ low doped with P type dopants, for example, for a P-channel flash memory device, and the layer of conductive material 234 may comprise other dimensions.

The floating gate material 234 and the flash tunnel oxide 232 are etched, e.g., using a reactive ion etch (RIE) slot etch, for example, forming the floating gate 234 and the floating gate oxide 232 of the flash memory cells 240. For example, a layer of photoresist may be formed over the top surface of the layer of conductive material 234. The layer of photoresist functions as a mask to form the floating gates of the flash memory cells 240 in the bitline direction, for example. The layer of photoresist is patterned to remove part of the layer of photoresist from over the STI region 250 and other regions of the semiconductor device 214, exposing part of the layer of conductive material 234. The exposed layer of conductive material 234 is removed, e.g., using a reactive ion etch (RIE) and using the layer of photoresist as a mask, although alternatively, other etch processes may be used. The etch process may be adapted to stop on the thin insulating layer 232, and may form slots that extend in a direction in and out of the page in the layer of conductive material 234, forming separating floating gates 234 for each flash memory cell 240, for example, as shown in FIG. 4. The conductive material 234 comprises strips of the conductive material 234 running in the bitline direction, e.g., in and out of the paper. The layer of photoresist is then removed.

Next, a control gate oxide 236 is formed over the floating gates 234 and the exposed portions of the second layer of semiconductive material 222. The control gate oxide 236 may comprise an insulating layer preferably comprising a thickness of about 12 to 25 nm, and may comprise a tri-layer of oxide/nitride/oxide (ONO) in one embodiment, as examples, although alternatively, the insulating layer of the control gate oxide 236 may comprise a high k dielectric material such as HfSiO₂, HfSiON, Al₂O₃, or other materials and dimensions. The control gate oxide 236 comprises an insulating layer between the floating gate 234 and the control gate 238 of the flash memory cells 240.

In one embodiment, the insulating layer of the control gate oxide 236 may comprise a first layer comprising a low temperature polysilicon oxide, a second layer comprising a low pressure chemical vapor deposition (LPCVD) nitride disposed over the first layer, and a third layer comprising a high temperature oxide disposed over the second layer. For example, the first layer may be formed by thermal oxidation of the semiconductor device 214 to about 900 degrees C., and exposing the conductive material 234 to oxygen; the second layer may be formed by depositing silicon nitride using LPCVD, and the third layer may be formed by heating the semiconductor device 214 in the presence of steam to oxidize the second layer at a temperature of about 900 degrees C., and/or depositing oxide or re-oxidizing the second layer of nitride to form silicon dioxide.

The control gate oxide 236 is removed from the peripheral regions (not shown) using an etch process, e.g., using a layer of photoresist as a mask, not shown. Then a high voltage gate oxidation process is used, e.g., using steam, to form a gate oxide in high voltage device areas (not shown). The oxidation process may also increase the thickness of the control gate oxide 236 in the flash memory cell region, for example. One or more layers and thicknesses of oxides may be formed in desired regions, depending on the type of peripheral circuitry used, for example, not shown.

In particular, for peripheral devices in the peripheral region comprising high voltage devices and circuitry, the insulating layers used for gate oxides preferably have a thickness of about 12 to 24 nm for high voltage circuitry, for example. For peripheral devices comprising low voltage devices and circuitry, the insulating layers used for gate oxides may comprise a thickness of about 1.5 to about 2.5 nm, as examples.

A dual gate oxide process may be used to form a gate oxide in low voltage device regions (not, shown) of the semiconductor device 214. For example, if the devices in the low voltage area of the peripheral region comprise logic applications, such as low voltage circuitry, e.g., having an operating voltage of about 3.0 V or less, and then the devices in the peripheral region (not shown) may be further divided into low leakage areas. In this case, another layer of photoresist (not shown) may be deposited after the formation of the high voltage area. The additional layer of photoresist is patterned to expose only the low leakage area in the peripheral region, followed by a wet etch and resist strip. Then, another insulating layer is thermally grown over the wells and over the second layer of semiconductor material 222 in the peripheral region. The processing sequence is then resumed to follow the above discussion of the low voltage device insulating layer formation. The dual formation of the insulating layer may be referred to as a “dual gate oxide” (DGO) formation process, for example. The insulating layer for low leakage areas preferably comprises a thickness of about 2 to 2.5 nm, and more preferably, may comprise a thickness of about 2.1 to 2.3 nm, in accordance with some embodiments of the present invention, as examples, in order to optimize low leakage and medium performance transistors in the optional low voltage circuit regions of the peripheral region of the semiconductor device 214.

Thus, the insulating layer may comprise one or more thicknesses in the peripheral region of the semiconductor device 214, depending on the insulating layer required for the particular type of devices formed in the peripheral region. The insulating layer may comprise a gate dielectric material for the devices formed in the peripheral region, for example, not shown.

The gate dielectric 228 of the select gate transistors 230 may be formed during the flash tunnel oxide 232 and control gate oxide 236 formation, or during the formation of the high voltage, low voltage, or peripheral region gate oxides, for example.

Then, a gate material 238 is deposited over the various oxides 228 and 236 (and in peripheral, high voltage, and low voltage regions, not shown) formed. The gate material 238 preferably comprises a conductive layer comprising a semiconductive material such as polysilicon, and preferably comprising a thickness of about 90 to 110 nm, as an example, although alternatively, the conductive layer 238 may comprise other materials and dimensions. The conductive layer 238 forms the control gates of the flash memory cells 240 in the flash memory region, over the insulating material of the control gate oxide 236.

An anti-reflective coating (ARC) (not shown) may be formed over the gate material 238, and the stacked gate materials 238, 236, and 234 are etched, e.g., using a RIE, to form the control gates 238 of the flash memory cells 240. To pattern the gate material 238, an insulating layer may be deposited over the conductive layer 238, e.g., over the ARC, for example. The insulating layer preferably comprises about 10 to 100 nm of tetra ethyl oxysilane (TEOS), as an example, although alternatively, the insulating layer may comprise other materials and dimensions. A layer of photoresist is deposited over the insulating layer and is patterned with a desired pattern for the control gates 238 of the flash memory cells 240 in the flash memory region. The insulating layer comprises a hard mask for patterning the flash memory cell control gates 238, for example. The layer of photoresist is used as a mask to pattern the insulating layer. The layer of photoresist is used as a mask to pattern the control gate and floating gate in the wordline direction, and thus may also be referred to as a “stacked gate mask.” The layer of photoresist may or may not be removed, and the insulating layer, and optionally, also the photoresist may be used as a mask to pattern the conductive layer 238 and the control gate oxide 236, as well as the floating gate 234, with the etch process stopping on the insulating layer 232. For example, a RIE process may be used to pattern the conductive layer 238, the control gate oxide 236, and the conductive layer 234. The flash memory cell 240 gates in the flash memory second region after the stacked gate mask etch process comprise a rectangular floating gate 234 in the wordline direction and a control gate 238 comprising a relatively long strip of conductive material along the wordline direction, for example.

The gates 226 and the gate oxide 228 of the select gate transistors 230 may be patterned during the control gate 238 patterning, and the gates 226 of the select gate transistors 230 may be formed from the same material layer as the control gates 238, for example.

The source and drain regions of the flash memory cells 240 and the select gate transistors 230 may then be formed by implanting dopants into the second layer of semiconductive material 222 through the insulating layer 228. For example, if the well comprises a P well, the source and drain regions 224 may comprise N junctions. The semiconductor device 214 is then annealed to diffuse the implanted dopants and form the source and drain regions 224, for example. The insulating layer comprising the hard mask is then removed, e.g., using a RIE or other removal process, and portions of the insulating layer 228 in areas other than the gate stack 238/236/234/232 of the flash memory cells 240 are also removed.

Next, processing of other regions of the semiconductor device 214 is then continued. For example, gates may be formed in other regions, and sidewalls of the gates may be oxidized, nitrided, or both, to form sidewall spacers, such as the spacers 242 shown in FIG. 4, e.g., by exposing the semiconductor device 214 to an oxygen-containing substance in a furnace, for example, although other methods may also be used. Portions of the second layer of semiconductive material 222 may be implanted with dopants to form extensions in the source and drain regions of the high voltage regions, logic regions, and low voltage regions (not shown). Silicides may be formed over one or more types of gates, insulating material 244 may be deposited over the entire structure, and contacts 246 may be formed in the insulating material 244, for example. One or more metallization layers M1, V1, M2, V2, M3, etc. may be formed over the insulating material 244 and contacts 246, for example.

The flash memory cells 240 in the flash memory region of the semiconductor device 214 are formed in an array of rows and columns, and may be addressed using conductive lines formed in metallization layers M1, M2, M3, etc., that are arranged in rows and columns, also referred to as wordlines WL and bitlines BL herein, for example. Each column of flash memory cells 240 is formed in a continuous region of the second layer of semiconductor material 222 and is separated from adjacent columns of flash memory cells by an STI region 250 such that the body of each flash memory cell 240 in a column is electrically coupled to the bodies of each other flash memory cell 240 in that column but is electrically isolated from the bodies of each flash memory cell 240 in other columns, for example. Thus, the bodies of the flash memory cells 240 in each column may be independently biased. The source of the select gate transistor with gate SG2 of each column may be coupled to the body of each column and may advantageously independently biased, allowing a further degree of freedom of applying voltages to the flash memory cells during read and write operations, advantageously. An electrical connection, e.g., a contact 246, is provided to each column of flash memory cells 240 so that the common well (P_well_of each column independently biasable with respect to the common well (P_well) of other columns of flash memory cells 240, for example. There may be hundreds or thousands of flash memory cells 240 formed in a flash memory region, for example, not shown, and there may be two or more flash memory regions on a single SOI substrate 216, for example. Likewise, in the peripheral region, there may be hundreds or thousands of transistors and other devices formed, and there may be two or more peripheral regions on a chip, for example, not shown.

The embodiments of the present invention shown in FIGS. 3 through 9 implemented in an SOI substrate 216 are advantageous in many ways. Implementing the structures on an SOI substrate 216 is particularly beneficial in isolated P well and uniform channel programming (UCP) program and erase schemes. Because STI regions 250 are used rather than deep trenches, lithography masks and etch processes to form the STI regions 250 are reduced and simplified. Because each column of the P wells may be biased independently, gate induced drain leakage (GIDL) is reduced or eliminated. Furthermore, a split-well bias may be used on unselected flash memory cells 240 during programming of selected flash memory cells 240, by biasing the source of the select gate transistors 230 with gates SG2 and the body of each column 252a and 252b, (see FIG. 5) preventing a gate disturb problem and a programming disturb problem. In addition, because each P well in a column is separated from other adjacent P wells by an STI region 250 and is contacted by a contact 246 or metallization layer, a floating body effect is eliminated. Because SOI substrates 216 are used, high performance SoC integration is implementable.

The NAND architecture of embodiments of the present invention achieves a dense flash memory cell 240 design. Flash memory cells 240 are connected in series between the bitlines and select lines, thus eliminating the requirement for contacts to the source and drain region of each flash memory cell 240 in a NAND unit cell, for example. For example, one basic NAND unit in a column has 16 stacked flash memory cells 240 connected in series, sandwiched between two select gate transistors 230, sharing one contact 246 to the drain DR of a select gate transistor 230 and one contact 246 to the source S of another select gate transistor 230 which is shorted to the common P well contact 246 of the column. Furthermore, each column contains numerous NAND unit cells which form many rows and columns of the stacked flash memory cells 240.

For example, in one preferred embodiment, a 4 Mbit array may comprise 4 sub-sections comprising 1 Mbit each, with row and column decoders (not shown) run in the center to minimize the access time. The 1 Mbit sub-array may be formed by 1024 rows (wordlines)×1024 columns (bitlines), for example. Each column may contain 64 NAND unit cells with 64 drain contacts 246 and 64 source contacts 246, comprising a total of 128 contacts. Thus, the entire 1 Mbit array may comprise only 131,000 contacts 246 to access all of the flash memory cells 240 in the array, thus making this NAND architecture a very dense array architecture. Advantageously, flash memory cells 240 having a cell area of about 4 to 7 F² are achievable in accordance with embodiments of the present invention, for example (e.g., wherein F is a minimum feature size of the integrated circuit). Alternatively, a flash memory array may be segmented in other configurations, for example, in accordance with embodiments of the present invention.

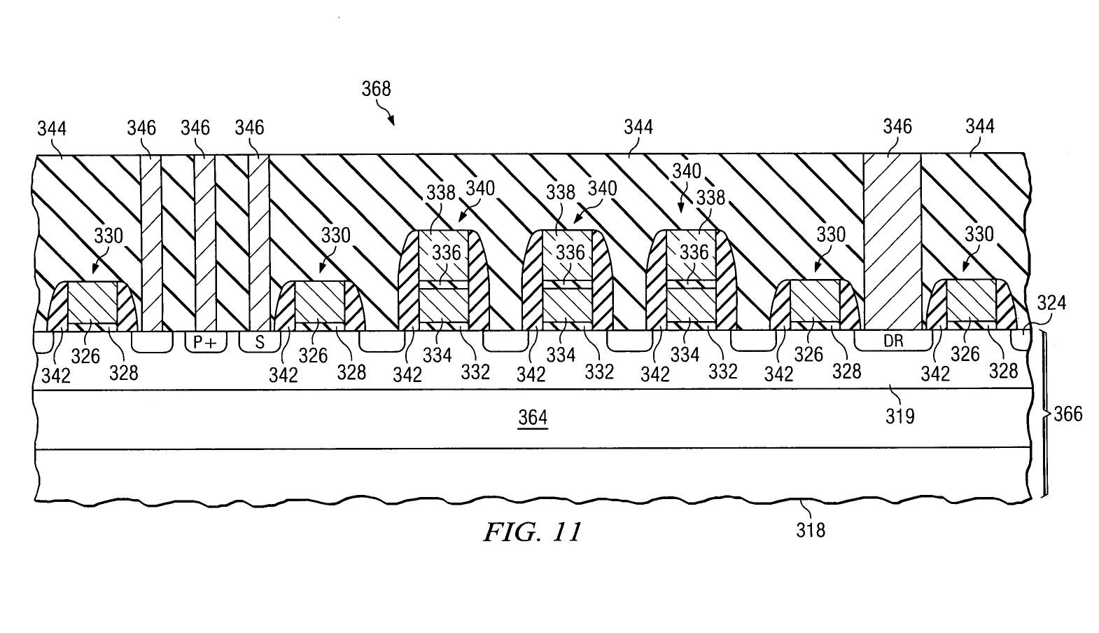

FIG. 10 is a schematic 360 of a column of flash memory cells 340 in accordance with another preferred embodiment of the present invention, wherein rather than using an SOI substrate, a workpiece 366 (see FIG. 11) is used that includes deep N wells (DNW) 364 formed in a bulk substrate 318, forming a triple well, and deep trench isolation (DTI) region 370 is used to provide isolation between adjacent P wells 319 (see FIG. 11) of columns of flash memory cells 340, as shown in a top view in FIG. 12. Like numerals are used as were used in the previous drawings, and to avoid repetition, each element is not described again herein in detail.

As in the previous embodiments, the isolated P well (IPW) NAND architecture includes a string of 16 floating gate cells 340 and 2 select gate transistors 330. The flash memory cells 340 are coupled in series, with adjacent flash memory cells 340 sharing a source and drain. The select gate transistors 330 are coupled at opposite ends of the flash memory cell 340 serial string. The common DNW 364 is coupled to the gate of each transistor 330 and 340 through the common P_well 319. The diodes 362 in the schematic 360 of FIG. 10 are not actual diodes 362: the diodes 362 shown represent a schematic of the P_well 319 to DNW 364, e.g., a bipolar effect of the p-region to n-region for P_well 319 isolation. The diodes 362 mimic the bipolar effect that occurs because the DNW 364 serves to isolate the leakage when the P_well 319 is electrically biased during programming, similar to the buried oxide underneath the common P_well 319 to provide an isolated P_well (IPW) concept of the embodiment shown in FIG. 4. In particular, the DNW 364 together with the DTI 370 may be used to replace the buried oxide layer BOX 220 of the SOI substrate 216 shown in the embodiment of FIG. 4, for example.

FIG. 11 shows a cross-sectional view of a portion of the memory device of FIG. 10 along a column in accordance with a preferred embodiment of the present invention. The IPW NAND architecture includes one select gate transistor 330 at the drain DR side. One select gate transistor 330 is coupled to the P well 319 in each column using an S/P_well contact to M3 (e.g. by contact 346 coupled to the source S in FIG. 11), for each of 32 wordlines in the memory array, for example.

Rather than using an SOI substrate 216 as in the first embodiment shown in FIG. 3 through 9, in the embodiments shown in FIGS. 10 through 12, first, a bulk substrate 318 is provided. The bulk substrate 318 may comprise a workpiece comprising Si, SiGe, Ge, or other semiconductor materials or combinations of semiconductive materials, as examples, having a thickness of about 400 μm or greater. P wells 319 and DNW's 364 are formed within and proximate the top of the substrate 318, e.g., by implantation of dopants and annealing the substrate 318, for example. Preferably before STI regions are formed in other regions of the semiconductor device 368 are formed, e.g., such as in peripheral regions, not shown, deep trenches 370 are formed in the substrate 318 between regions that will comprise columns of flash memory cells 340. The deep trenches (see DTI 370 in a top view in FIG. 12) preferably extend at least to the top of the DNW 364 shown in FIG. 11, for example, and in some embodiments preferably extend at least partially through the DNW 364. The deep trenches preferably comprise a depth from a top surface of the substrate 318 of about 400 nm or greater, as an example. The deep trenches are filled with an insulating material, such as an oxide, a nitride, insulating liners, or combinations thereof, for example. A portion of the deep trenches may also be filled with polysilicon in some embodiments, for example.

After the formation of the deep trench isolation 370, processing of the semiconductor device is continued as described with regard to the previous embodiment described herein and illustrated in FIGS. 3 through 9, for example, forming serial strings of flash memory cells 340 in a plurality of columns, wherein the DTI 370 between the columns of flash memory cells 340 provides isolation between the P wells 319 of the flash memory cells 340 coupled to the flash memory cell 340 bodies.

FIG. 12 shows two columns of memory cells 340 separated by a deep trench isolation (DTI) region 370 in accordance with a preferred embodiment of the present invention. In this embodiment, deep trench isolation (DTI) regions 370 are used to isolate the P wells 319 in adjacent columns of flash memory cells in the NAND arrangement from one another. By using a common DNW 364, and by being able to selectively and/or split-bias the source of the select gate transistor SG2 and the P well S/P_well of each column 352a and 352b, a greater degree of freedom is achieved in biasing the unselected flash memory cells 340 adjacent to those that are being programmed 340a, achieving non-disturbed adjacent flash memory cells 340b and 340c, for example.

In the embodiments shown in FIGS. 10 through 12, a deep trench isolation process is used prior to STI formation in other regions, to form the DTI regions 370. The DNW 364 are implanted a predetermined distance in predetermined locations in the flash memory region beneath the top surface of the bulk substrate 318, for example, and the semiconductor device 368 is annealed to form the DNW 364. The DNW 364 may be biased, e.g., by electrically contacting the DNW 364 elsewhere on the device 368 (not shown). Thus, the same bias scheme may be used as described for the first embodiment, and further including a DNW 364 bias.

In FIG. 12, another bias scheme 372 in accordance with an embodiment of the present invention is illustrated, using an isolated P well for an NAND architecture formed with deep trench isolation. Because each column of flash memory cells is coupled to an isolated P well, the P well of each column may be biased independently, eliminating GIDL and punch-through problems. Again, a split-well bias scheme may be used to eliminate gate disturb problems that can occur in a NAND arrangement of flash memory cells.

Table 2 and FIG. 12 illustrate an exemplary bias scheme for an embodiment including isolated P wells and a common DNW.

TABLE 2

| | SG1 | SG2 | WL1-16 | WL_sel | BL1 | BL2_sel | S1/PW1 | S2/PW2 | DNW |
|---|---|---|---|---|---|---|---|---|---|
| Write | 0 | 0 | 4 | 13 | 4 | −4 | 4 | −4 | 4 |
| Erase | 4 | 4 | −13 | −13 | 4 | 4 | 4 | 4 | 4 |
| Read | 4.5 | 4.5 | 4.5 | 0 | 0 | 1 | 0 | 0 | 0 |

In this embodiment, the deep N well 364 is set at a particular voltage, such as 4 V, during the write and erase operation, and the deep N well 364 is set at 0 V during a read operation, as examples. The other voltage levels and biases are similar to the voltages shown in Table 1 for the first embodiment shown in FIGS. 3 through 9, for example. The particular voltages described herein merely provide an example of operating a particular memory array: other biasing and operating schemes are also possible, for example.

Embodiments of the present invention provide manufacturing processes and structures for flash memory devices formed on SOI substrates and standard types of substrates. The manufacturing process flow is more efficient and less costly, requiring a reduced number of lithography masks and manufacturing process steps, and provides the ability to further reduce the size of flash memory cells. Advantageously, an isolated P well bias scheme is preserved, and each column of P wells may be biased independently, resulting in reduced or eliminated GIDL. A NAND architecture is implemented, requiring fewer contacts to drains and sources of the flash memory cells, and the flash memory cell size can be reduced, e.g., to about 4 to 7 F².

Further advantages of embodiments of the present invention include providing the ability to reduce the size of peripheral devices. For example, the size of charge pump devices and/or high voltage devices in the peripheral support circuitry may be able to be reduced and scaled down in size. Referring again to FIG. 5, when flash memory cell 240a is selected for programming, a voltage of 13 V is applied to WL2, a voltage of −4 V is applied to BL2 and to the S/P_well of column 252b. Thus, a total programming voltage of 17 V is achieved although 13 V is the maximum voltage applied, allowing the scaling of the peripheral components and circuits that supply the voltages for the flash memory array, for example.

Embodiments of the present invention have been described herein wherein the flash memory devices comprise n-channel flash memory devices. However, embodiments of the present invention may also comprise memory arrays comprising P-channel flash memory devices, for example.

Advantageously, in accordance with embodiments of the present invention, contacts 246 are made to P wells or body of the flash memory devices 240 for each column of the flash memory cells, so that the P wells may be biased or connected to a predetermined voltage level. For example, the P wells are preferably biased to a voltage level of about −10 V to about +10 V. Advantageously, an additional biasing terminal, e.g., at the source of the select gate transistors SG2 of each column 252a or 252b, wherein the source is coupled to the P well of the column 252a and 252b, enables the ability to split-bias the flash memory cells.

For example, if a bitline or column is selected, a negative voltage may be used to bias the selected P well of the selected column of flash memory cells more negatively than if the bitline was not selected, in which case, the same voltage but with a positive polarity could be used to bias the unselected P well of the unselected column of flash memory cells. However, alternatively, the P wells may be biased to other voltage levels, for example.

When a P well is biased negatively, the overall vertical field (e.g., the sum of gate-to-well field) is enhanced, which provides a favorable condition for electrons tunneling from the channel regions in the P well to the floating gate. However, when the P well is biased positively, the overall gate-to-well vertical field is reduced, known as an inhibited effect, which is a necessary condition to suppress electron tunneling from occurring, thus reducing the gate disturb effect in unselected columns. Thus, an additional advantage of embodiments of the present invention is providing a flash memory device design wherein isolated P wells of columns of flash memory cells provide bias flexibility.

Embodiments of the present invention may be implemented in flash memory cell structures comprising twin-wells, or alternatively, may be implemented in triple well configurations. Embodiments of the present invention include structures for semiconductor devices and methods of manufacturing thereof. Embodiments of the present invention also include methods of operating flash memory arrays.

The array of flash memory cells 240 may be formed on an SOI substrate 216 (see FIGS. 4 and 9) or on a bulk substrate including a twin or triple well formed thereon, wherein the twin wells, triple wells, or SOI substrate 216 prevent a punch-through of source and drain junctions of the flash memory cells 240. In other embodiments, the isolation regions between the common wells of the columns may comprise DTI regions 370 with a DNW disposed beneath the common wells, wherein the DTI regions 370 prevent punch-through of source and drain junctions of the flash memory cells 340, for example.

Embodiments of the invention may be implemented in embedded flash memory devices, as described herein, in system on a chip (SoC) devices such as microprocessors for high performance applications, microcontrollers, or DSP for low power portable applications with other embedded memories such as SRAM or DRAM devices, as examples. Embodiments of the present invention may also be used in stand-alone flash memory arrays or in stand-alone flash memory devices, as examples.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of operating a memory array, the method comprising:
providing an array of memory cells arranged in rows and columns, each column comprising a NAND unit cell comprising a plurality of memory cells coupled together serially, the plurality of memory cells of each NAND unit cell sharing a common well, the common well of each column being separated from common wells of adjacent columns by an isolation region, each NAND unit cell including a select gate transistor coupled to a memory cell in the column, a source of the select gate transistor being coupled to the common well of the NAND unit cell; and
accessing a first memory cell in a column by biasing the common well of the NAND unit cell of the first memory cell differently than the common well of other NAND unit cells are biased.

2. The method according to claim 1, wherein accessing the first memory cell comprises reading or writing to the first memory cell.

3. The method according to claim 1, wherein biasing the common well of the NAND unit cell of the first memory cell comprises biasing the common well of the NAND unit cell of the first memory cell with an opposite polarity than the common well of NAND unit cells of unselected memory cells of other columns are biased.

4. The method according to claim 1, wherein each memory cell in a row is coupled to a wordline, wherein biasing the common well of the NAND unit cell of the first memory cell differently than the common well of other NAND unit cells are biased comprises biasing the common well of the NAND unit cell of the first memory cell to a first voltage, further comprising biasing a wordline of the first memory cell to a second voltage, wherein the second voltage comprises a voltage having an opposite polarity than the first voltage.

5. The method according to claim 1, wherein the plurality of memory cells comprise flash memory cells, and wherein biasing the common well of the NAND unit cell of the first memory cell differently than the common well of other NAND unit cells are biased comprises preventing disturbing unselected memory cells in columns and rows adjacent to the first memory cell.

6. The method according to claim 1, wherein providing the array of memory cells comprises providing an array of flash memory cells formed on a silicon-on-insulator (SOI) substrate or on a bulk substrate including a twin or triple well formed thereon, wherein the twin wells, triple wells, or SOI substrate prevent a punch-through of source and drain junctions of the flash memory cells.

7. The method according to claim 1, wherein providing the array of memory cells comprises providing an array of flash memory cells formed on a bulk substrate, wherein the isolation regions between the common wells comprise deep trench isolation (DTI) regions, wherein a deep n well (DNW) is disposed beneath the common wells, and wherein the DTI regions prevent a punch-through of source and drain junctions of the flash memory cells.

8. A method of operating a flash memory array, the method comprising:
providing an array of flash memory cells arranged rows and columns, each column of flash memory cells sharing a common well, the common well of each column being isolated from adjacent columns of the flash memory cells by an isolation region, each flash memory cell comprising a gate, a drain, a source, and a body, the body of each flash memory cell being coupled to the common well of the column, each column of flash memory cells being coupled together serially in a string, the sources of flash memory cells in each string being coupled to the drains of adjacent flash memory cells, each column comprising blocks of NAND unit cells including a first select gate transistor coupled to a drain of a flash memory cell at one end of the string and a second select gate transistor coupled to a source of a flash memory cell at an opposite end of the string, wherein a drain contact is shared between at least two first select gate transistors of at least two NAND unit cells; and
selecting a flash memory cell in one of the columns by applying a first voltage to a gate of the first select gate transistor of all columns, applying a second voltage to a gate of the second select gate transistor of all columns, applying a third voltage to a drain of the first select gate transistor in columns of unselected flash memory cells, applying a fourth voltage to a drain of the first select gate transistor in the column of the selected flash memory cell, applying a fifth voltage to a source of the second select gate transistor in columns of unselected flash memory cells, and applying a sixth voltage to the common well and to a source of the second select gate transistor in the column of the selected flash memory cell, while programming the selected flash memory cell.

9. The method according to claim 8, further comprising isolating columns of NAND unit cells containing unselected flash memory cells using the second select gate transistor in each column, preventing a leakage current from flowing to other NAND unit cells along the same column or in the isolated columns of NAND unit cells containing unselected flash memory cells when the selected flash memory cell is selected.

10. The method according to claim 8, wherein the source of each second select gate transistor is shorted to an isolated contact coupled to the common well of the column, and wherein the isolated common wells of the columns are independently biasable.

11. The method according to claim 8, wherein programming the selected flash memory cell comprises applying a seventh voltage to a wordline coupled to the gates of a row of flash memory cells, the selected flash memory cell being disposed on the row that the seventh voltage is applied to.

12. The method according to claim 11, further comprising applying an eighth voltage to wordlines coupled to the gates of rows of unselected flash memory cells.

13. The method according to claim 8, wherein programming the selected flash memory cell comprises applying a gate to channel voltage differential of about 15 V or greater to the selected flash memory cell.

14. The method according to claim 8, wherein applying the first voltage, the second voltage, the third voltage, the fourth voltage, the fifth voltage, and the sixth voltage comprise applying a voltage of about −10 V to about +10 V.

15. The method according to claim 8, wherein applying the first voltage, the second voltage, the third voltage, the fourth voltage, the fifth voltage, and the sixth voltage comprise applying a total voltage difference across the gates to channels of the flash memory cells in the array of about 10 V or less.

16. The method according to claim 8, wherein the isolation region separating the common well of the columns from adjacent columns, applying the fifth voltage to the source of the second select gate transistor in columns of unselected flash memory cells, and applying the sixth voltage to the common well and to the source of the second select gate transistor in the column of the selected flash memory cell reduce a program or a gate disturb along a wordline or bitline coupled to the selected flash memory cell.

17. A method of manufacturing a semiconductor device, the method comprising:
providing a substrate;
forming an array of flash memory cells on the substrate, the array of flash memory cells being arranged in rows and columns in a NAND architecture, each column comprising a plurality of flash memory cells being coupled together serially in a NAND unit cell and sharing a common well;
forming a plurality of isolation regions in the substrate so that each column of the plurality of flash memory cells is separated from adjacent columns of flash memory cells by one of the plurality of isolation regions; and
providing an electrical connection to each column of flash memory cells so that the common well of each column independently biasable with respect to the common well of other columns of flash memory cells.

18. The method according to claim 17, further comprising forming at least one select gate transistor coupled to each column of serially coupled flash memory cells, a source of the at least one select gate transistor of each column being coupled to the common well of each column.

19. The method according to claim 17, wherein forming the array of flash memory cells on the substrate comprises forming the array of flash memory cells in at least one flash memory region of the substrate, wherein the method further comprises forming a plurality of peripheral devices in at least one peripheral region of the substrate, and wherein the plurality of peripheral devices are operationally coupled to the plurality of flash memory cells, or wherein the peripheral devices perform functions unrelated to the access of information to or from the flash memory cells.

20. The method according to claim 19, wherein forming the plurality of peripheral devices in the at least one peripheral region comprises forming logic devices, high voltage devices, low voltage devices, power devices, control devices, and/or combinations thereof.

21. The method according to claim 17, wherein manufacturing the semiconductor device comprises manufacturing a stand-alone flash memory device.

22. A semiconductor device, comprising:
a substrate;
a plurality of isolation regions disposed on a top portion of the substrate; and
a plurality of flash memory cells formed on the substrate, the plurality of flash memory cells being arranged in an array of rows and columns, each column comprising a plurality of flash memory cells comprising a NAND unit cell, the flash memory cells of each NAND unit cell being coupled together serially and sharing a common well, each column of flash memory cells being separated from adjacent columns of flash memory cells by one of the plurality of isolation regions, and wherein each NAND unit cell includes a select gate transistor, a source of the select gate transistor being coupled to the common well of each column.

23. The semiconductor device according to claim 22, wherein the common well of each column is biasable to a predetermined voltage, and wherein the common wells of adjacent NAND unit cells are biasable to different voltages.

24. The semiconductor device according to claim 23, wherein the predetermined voltage comprises about ±10 volts or less.

25. The semiconductor device according to claim 22, further comprising at least one contact coupled to each column of flash memory cells.

26. The semiconductor device according to claim 22, wherein the plurality of isolation regions comprise shallow trench isolation regions having a depth within the substrate of about 400 nm or less, or deep trench isolation regions having a depth within the substrate of about 400 nm or greater.
